(19) United States
(12) Patent Application Publication
(10) Pub. No.: US 2024/0088339 A1
(43) Pub. Date: Mar. 14, 2024

(54) SEMICONDUCTOR DEVICE AND METHOD FOR MANUFACTURING SAME

(71) Applicants: Kabushiki Kaisha Toshiba, Tokyo (JP); Toshiba Electronic Devices & Storage Corporation, Tokyo (JP)

(72) Inventor: Kiyohisa ICHIKAWA, Buzen Fukuoka (JP)

(21) Appl. No.: 18/118,684

(22) Filed: Mar. 7, 2023

(30) Foreign Application Priority Data
Sep. 9, 2022 (JP) 2022-143858

(51) Int. Cl. H01L 33/62; H01L 33/56

(52) U.S. Cl. CPC H01L 33/62; H01L 33/56; H01L 2933/005; H01L 2933/0066

(57) ABSTRACT

A semiconductor device includes an insulating base material including first and second surfaces, the second surface being a back surface at a side opposite to the first surface; a plurality of metal pads provided on the first surface of the insulating base material, the plurality of metal pads being apart from each other; a first semiconductor element provided on one of the metal pads; a first resin provided on the first surface of the insulating base material, the first surface of the insulating base material including first and second regions, the plurality of metal pads being provided on the first region of the first surface, the first resin covering the second region of the first surface; and a second resin provided at the first surface side of the insulating base material, the second resin contacting the first resin and sealing the semiconductor element at the first surface side.

### CROSS-REFERENCE TO RELATED APPLICATIONS

This application is based upon and claims the benefit of priority from Japanese Patent Application No. 2022-143858, filed on Sep. 9, 2022; the entire contents of which are incorporated herein by reference.

### FIELD

Embodiments relate to a semiconductor device and a method for manufacturing the same.

### BACKGROUND

A resin-sealed semiconductor device is required to be downsize while a chip size of a semiconductor element is increased year by year, and the occupied volume of the sealing resin increases thereby. In such a device, the hermeticity for the external environment also required.

### BRIEF DESCRIPTION OF THE DRAWINGS

FIG. 1 is a schematic perspective view showing a semiconductor device according to an embodiment;

FIG. 2 is a schematic cross-sectional view showing the semiconductor device according to the embodiment;

FIG. 3 is a schematic plan view showing a substrate of the semiconductor device according to the embodiment;

FIGS. 4A to 4D are schematic cross-sectional views showing manufacturing processes of the substrate of the semiconductor device according to the embodiment; and

FIGS. 5A and 5B are schematic cross-sectional views showing another manufacturing process of the substrate of the semiconductor device according to the embodiment.

### DETAILED DESCRIPTION

According to one embodiment, a semiconductor device includes an insulating base material including a first surface and a second surface, the second surface being a back surface at a side opposite to the first surface; a plurality of metal pads provided on the first surface of the insulating base material, the plurality of metal pads being apart from each other; a first semiconductor element provided on one of the metal pads; a first resin provided on the first surface of the insulating base material, the first surface of the insulating base material including first and second regions, the plurality of metal pads being provided on the first region of the first surface, the first resin covering the second region of the first surface; and a second resin provided at the first surface side of the insulating base material, the second resin contacting the first resin and sealing the semiconductor element at the first surface side.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

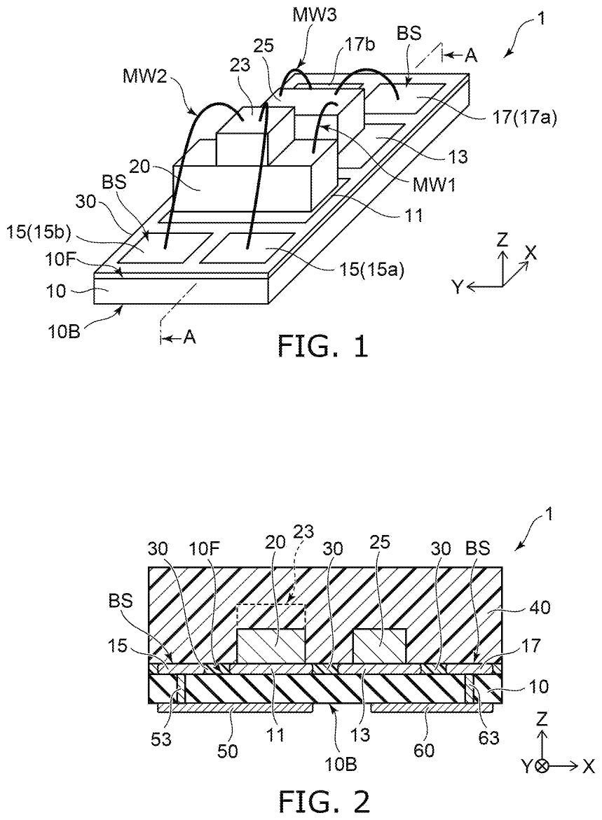

FIG. 1 is a schematic perspective view showing a semiconductor device 1 according to an embodiment. The semiconductor device 1 is, for example, a photorelay. The semiconductor device 1 includes, for example, an insulating base material 10, a semiconductor element 20, and a first resin 30.

The insulating base material 10 is, for example, a glass epoxy substrate. The insulating base material 10 includes a first surface 10F, and a second surface 10B that is the back surface of the insulating base material 10. The insulating base material 10 has a thickness of 50 to 2000 micrometers in the direction from the second surface toward the first surface, e.g., a Z-direction. Multiple metal pads are provided on the first surface 10F of the insulating base material 10. The multiple metal pads are apart from each other. The multiple metal pads include, for example, copper (Cu). The multiple metal pads include, for example, metal pads 11, 13, 15, and 17.

The semiconductor element 20 is mounted on the metal pad 11 on the insulating base material 10. The semiconductor element 20 is, for example, a silicon photodiode. The semiconductor element 20 is connected to the metal pad 11 via, for example, a connection member (not illustrated) such as a insulative paste, etc.

According to the embodiment, a semiconductor element 23 is mounted on the semiconductor element 20. The semiconductor element 23 is, for example, a light-emitting diode. The semiconductor element 23 is connected to the semiconductor element 20 via, for example, a connection member (not illustrated) such as a transparent resin, etc. The semiconductor element 20 and the semiconductor element 23 are optically coupled.

Another semiconductor element 25 is mounted on the metal pad 13. The semiconductor element 25 is, for example, a MOS transistor. The semiconductor element 25 is connected to the metal pad 13 via another connection member (not illustrated). Also, the semiconductor element 25 is electrically connected to the semiconductor element 20 via a conductive member MW1, e.g., a metal wire. The metal pad 13 may be subdivided; and the semiconductor element 25 may be mounted on each of the pads and connected by conductive members.

As shown in FIG. 1, the metal pads 15 and 17 are provided on the first surface 10F of the insulating base material 10. The metal pads 15 and 17 are, for example, bonding pads. The semiconductor element 23 includes, for example, an anode and a cathode electrically connected respectively to metal pads 15a and 15b via conductive members MW2. The semiconductor element 25 includes, for example, a source and a drain electrically connected respectively to metal pads 17a and 17b via other conductive members MW3. The semiconductor elements include, for example, a pair of MOS transistors connected to each other. When the sources of the pair of MOS transistors connected to each other, the drains are connected respectively to the metal pad 17a and the metal pad 17b. When the drains of the pair of MOS transistors are connected to each other, the sources are connected respectively to the metal pad 17a and the metal pad 17b.

Herein, there is a case in which the metal pads 15a and 15b are referred to as the metal pad 15 without differentiating. The metal pads 17a and 17b and the conductive members MW1 to MW3 also are similarly described.

The first resin 30 is provided on the first surface 10F of the insulating base material 10. The first resin 30 covers, for example, the entire first surface 10F other than the region at which the multiple metal pads are provided. The first resin 30 contacts the outer edges of the multiple metal pads. In other words, the first resin 30 does not cover bonding surfaces BS of the multiple metal pads. The first resin 30 is, for example, polyamideimide.

FIG. 2 is a schematic cross-sectional view showing the semiconductor device 1 according to the embodiment. FIG. 2 is a cross section of the semiconductor device 1 along A-A line in FIG. 1. As shown in FIG. 2, the semiconductor device 1 further includes a second resin 40, a first connection terminal 50, and a second connection terminal 60.

The second resin 40 is provided at the first surface 10F side of the insulating base material 10 and covers the semiconductor elements 20, 23, and 25, the conductive members MW1 to MW3, and the metal pads 11, 13, 15 and 17. The second resin 40 is, for example, an epoxy resin. The second resin 40 contacts the first resin 30.

The metal pads 11, 13, 15, and 17 are arranged, for example, in an X-direction; and the metal pads 11 and 13 are provided between the metal pad 15 and the metal pad 17. The metal pad 11 is positioned between the metal pad 13 and the metal pad 15. The metal pad 13 is positioned between the metal pad 11 and the metal pad 17.

The second resin 40 contacts the first resin 30 between the metal pad 11 and the metal pad 15, between the metal pad 11 and the metal pad 13, and between the metal pad 13 and the metal pad 17. Also, the second resin 40 contacts the first resin 30 at the peripheral edge portion of the insulating base material 10 surrounding the multiple metal pads.

The adhesion strength between the insulating base material 10 and the first resin 30 is, for example, greater than the adhesion strength between the insulating base material 10 and the second resin 40. The adhesion strength between the first resin 30 and the second resin 40 also is greater than the adhesion strength between the insulating base material 10 and the second resin 40. The adhesion strength between the metal pads 11, 13, 15, and 17 and the second resin 40 is less than the adhesion strength between the insulating base material 10 and the first resin 30 and the adhesion strength between the first resin 30 and the second resin 40. The adhesion strength between the second resin 40 and the multiple elements is less than the adhesion strength between the insulating base material 10 and the first resin 30 and the adhesion strength between the first resin 30 and the second resin 40. In other words, compared to when the second resin 40 is directly provided on the insulating base material 10, it is possible to increase the adhesion strength of the second resin 40 by interposing the first resin 30 surrounding the metal pads. Thereby, it is possible to improve the hermeticity for the external environment even when the metal pads of the multiple semiconductor elements are enlarged, and increase the reliability of the semiconductor device. For example, the magnitude of the adhesion strength can be determined using a mechanical peel test.

The first resin 30 has preferably the hardness less than the hardness of the second resin 40. That is, in the semiconductor device 1, the resistance to the stress can be improved by the flexible first resin 30. The hermeticity of the semiconductor device 1 for the external environment can be improved thereby, and the reliability of the semiconductor elements 20, 23, and 25 can be increased.

The first connection terminal 50 and the second connection terminal 60 are provided on the second surface 10B of the insulating base material 10. The first connection terminal 50 and the second connection terminal 60 are, for example, metal layers that include copper Cu.

The first connection terminal 50 is electrically connected to the metal pad 15 via a connection member 53 provided in the insulating base material 10. For example, two first connection terminals 50 are provided on the second surface 10B of the insulating base material 10 and connected respectively to the metal pads 15a and 15b (see FIG. 1).

The second connection terminal 60 is electrically connected to the metal pad 17 via a connection member 63 provided in the insulating base material 10. For example, two second connection terminals 60 are provided on the second surface 10B of the insulating base material 10 and connected respectively to the metal pads 17a and 17b (see FIG. 1).

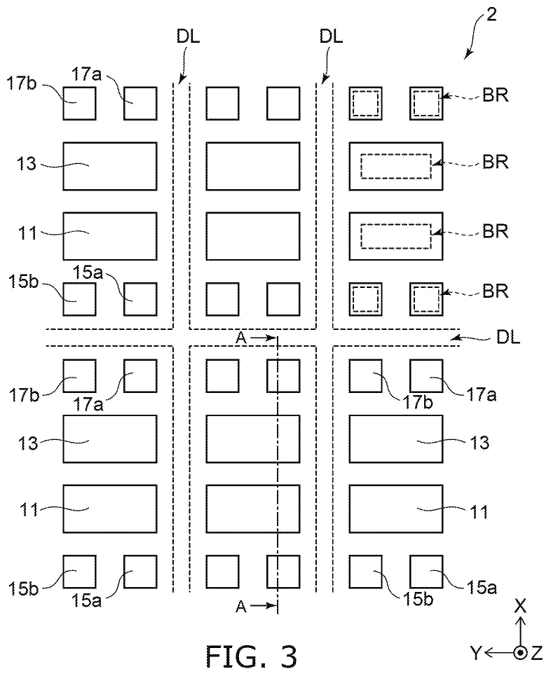

FIG. 3 is a schematic plan view showing a substrate 2 of the semiconductor device according to the embodiment. FIG. 3 illustrates the multiple metal pads provided on the first surface 10F of the insulating base material 10. Each metal pad includes a bonding region BR in the bonding surface BS (see FIG. 1). For example, the semiconductor elements 20, 23, and 25 are mounted at the first surface 10F side (see FIG. 1) and molded using the second resin 40 (see FIG. 2). Thereafter, the multiple semiconductor devices 1 are cut out by cutting substrate 2 along a dicing line DL.

The first resin 30 is provided on the first surface 10F of the insulating base material 10 exposed between the metal pads that are next to each other and between the dicing line DL and the metal pads. However, when the semiconductor device 1 is downsized, the space between the multiple metal pads is reduced, and the spacing between the dicing line DL and the metal pads also is reduced. As a result, it is difficult to provide the first resin 30 without covering the metal pads on the first surface 10F of the insulating base material 10. The bonding strength of the semiconductor elements 20 and 25 may be reduced if the first resin 30 or components of the first resin 30 remain on the bonding regions BR of the metal pads 11 and 13. Also, the bonding strength of the conductive members MW bonded on the metal pads 15 and 17 is reduced. Therefore, the reliability of the semiconductor device 1 is degraded.

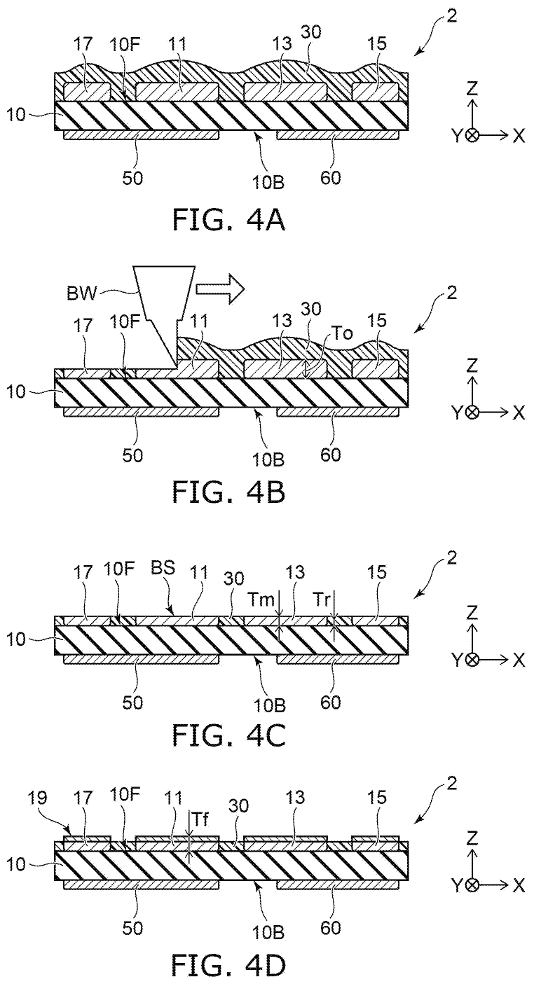

FIGS. 4A to 4D are schematic cross-sectional views showing manufacturing processes of the substrate 2 of the semiconductor device according to the embodiment. FIGS. 4A to 4D are schematic views illustrating a cross section along line A-A shown in FIG. 3.

As shown in FIG. 4A, the first resin 30 is coated and cured on the first surface 10F side of the insulating base material 10. The first resin 30 is coated onto, for example, the entire surface of the first surface 10F and covers the multiple metal pads.

As shown in FIG. 4B, the first resin 30 and the surface layers of the metal pads are cut away by using a cutting blade BW. The cutting blade BW is moved in a direction parallel to the first surface 10F while maintaining constant spacing from the first surface 10F of the insulating base material 10. The spacing between the cutting blade BW and the first surface 10F of the insulating base material 10 is, for example, less than the Z-direction thickness To of the metal pads before cutting.

As shown in FIG. 4C, surfaces of the metal pads are exposed, and the first resin 30 remains between the metal pads that are next to each other. A thickness Tr in the Z-direction of the first resin 30 is substantially equal to a thickness Tm in the Z-direction of the metal pads.

As shown in FIG. 4D, a metal layer 19 may be formed on the surfaces of the metal pads. The metal layer 19 includes, for example, gold (Au) or nickel (Ni). The metal layer 19 is formed using, for example, plating. The total thickness Tf in the Z-direction of the metal pads that includes the thickness of the metal layer 19 is greater than the thickness Tr of the first resin 30. The difference between the thicknesses Tf and Tr may be, for example, several dozen micrometers. The difference between the thicknesses Tf and Tr may be preferably less than 10 micrometers. The first resin 30 may be provided on the first surface 10F with so-called an anchor effect due to such a height difference between each metal pads and the first resin 30. Thereby, it is possible to increase a resistance against a peel force parallel to the first surface 10F of the insulating base material 10 and improve the adhesiveness of the first resin 30 to the insulating base material 10.

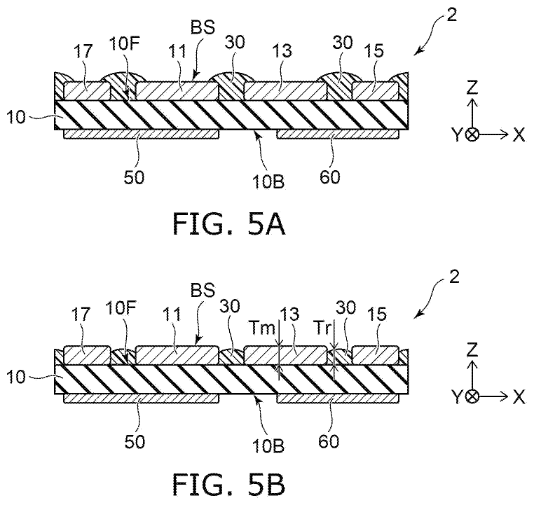

FIGS. 5A and 5B are schematic cross-sectional views showing another manufacturing process of the substrate 2 of the semiconductor device according to the embodiment. FIGS. 5A and 5B are schematic views illustrating the cross section along line A-A shown in FIG. 3.

As shown in FIG. 5A, the first resin 30 is coated onto the first surface 10F of the insulating base material 10 between the metal pads that are next to each other. The first resin 30 is selectively coated using, for example, a dispenser. When the space between the metal pads that are next to each other is narrow, it is no longer possible in such a case to prevent the first resin 30 from spreading to the bonding surfaces BS of the metal pads.

As shown in FIG. 5B, the first resin 30 is partially removed by, for example, plasma etching. In other words, the first resin 30 is removed so that a portion of the first resin 30 remains between the metal pads that are next to each other, and covers the first surface 10F. Thereby, it is possible in each bonding region BR (see FIG. 3) of the metal pads to remove the first resin 30 and the components of the first resin 30. The first resin 30 is preferably etched such that the thickness Tr in the Z-direction of the first resin 30 is less than the thickness Tm in the Z-direction of the metal pads. Moreover, the first resin 30 includes edge portions and other portion provided between the metal pads 11, 13, 15, and 17. The edge portions contact the metal pads 11, 13, 15, and 17, and the other portion is positioned between the edge portions. The edge portions is provided with the thicknesses preferably less than a thickness of the other portion. Thereby, it is possible for the first resin 30 to increase the adhesiveness to the insulating base material 10 by the anchor effect.

The semiconductor device according to the embodiment including the following aspects:

(Note 1)

A semiconductor device, comprising:
an insulating base material including a first surface and a second surface, the second surface being a back surface at a side opposite to the first surface;
a plurality of metal pads provided on the first surface of the insulating base material, the plurality of metal pads being apart from each other;
a first semiconductor element provided on one of the metal pads;
a first resin provided on the first surface of the insulating base material, the first surface of the insulating base material including first and second regions, the plurality of metal pads being provided on the first region of the first surface, the first resin covering the second region of the first surface; and
a second resin provided at the first surface side of the insulating base material, the second resin contacting the first resin and sealing the semiconductor element at the first surface side.

(Note 2)

The device according to note 1, wherein the first resin has a thickness in a first direction perpendicular to the first surface of the insulating base material, the thickness of the first resin being equal to or less than a thickness of the plurality of metal pads in the first direction.

(Note 3)

The device according to note 1 or 2, wherein the first resin has a hardness less than a hardness of the second resin.

(Note 4)

The device according to any one of notes 1 to 3, wherein
the first resin has an adhesion strength to the insulating base material, the adhesion strength of the first resin being greater than an adhesion strength of the second resin to the insulating base material.

(Note 5)

The device according to any one of notes 1 to 4, further comprising a second semiconductor element other than the first semiconductor element, wherein
the plurality of metal pads include a first metal pad and a second metal pad next to the first metal pad, the semiconductor element being provided on the first metal pad, the second semiconductor element being provided on the second metal pad,
the first semiconductor element and the second semiconductor element are electrically connected via a conductive member, and
the second resin seals the first semiconductor element, the second semiconductor element, and the conductive member at the first surface side of the insulating base material.

(Note 6)

The device according to any one of notes 1 to 5, further comprising:
a third semiconductor element provided on the first semiconductor element; and
a connection terminal provided on the second surface of the insulating base material, wherein
the plurality of metal pads further include a third metal pad electrically connected to the third semiconductor element via another conductive member, the third metal pad being electrically connected to the connection terminal.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and overview of the invention.

What is claimed is:

1. A semiconductor device, comprising:
an insulating base material including a first surface and a second surface, the second surface being a back surface at a side opposite to the first surface;
a plurality of metal pads provided on the first surface of the insulating base material, the plurality of metal pads being apart from each other;
a first semiconductor element provided on one of the metal pads;
a first resin provided on the first surface of the insulating base material, the first surface of the insulating base material including first and second regions, the plurality of metal pads being provided on the first region of the first surface, the first resin covering the second region of the first surface; and
a second resin provided at the first surface side of the insulating base material, the second resin contacting the first resin and sealing the semiconductor element at the first surface side.

2. The device according to claim 1, wherein
the first resin has a thickness in a first direction perpendicular to the first surface of the insulating base material, the thickness of the first resin being equal to or less than a thickness of the plurality of metal pads in the first direction.

3. The device according to claim 1, wherein
the first resin has a hardness less than a hardness of the second resin.

4. The device according to claim 1, wherein
the first resin has an adhesion strength to the insulating base material, the adhesion strength of the first resin being greater than an adhesion strength of the second resin to the insulating base material.

5. The device according to claim 1, further comprising:
metal layers provided on the plurality of metal pads, respectively, the metal layers including material different from material of the metal pads.

6. The device according to claim 1, further comprising:
a second semiconductor element other than the first semiconductor element,
the plurality of metal pads including a first metal pad and a second metal pad next to the first metal pad, the semiconductor element being provided on the first metal pad, the second semiconductor element being provided on the second metal pad,
the first semiconductor element and the second semiconductor element being electrically connected via a conductive member,
the second resin sealing the first semiconductor element, the second semiconductor element, and the conductive member at the first surface side of the insulating base material.

7. The device according to claim 1, further comprising:
a third semiconductor element provided on the first semiconductor element; and
a connection terminal provided on the second surface of the insulating base material,
the plurality of metal pads further including a third metal pad electrically connected to the third semiconductor element via another conductive member, the third metal pad being electrically connected to the connection terminal.

8. A method for manufacturing a semiconductor device, the method comprising:
providing an insulating base material with a plurality of metal pads, the insulating base material including a first surface, the plurality of metal pads being provided on the first surface;
forming a first resin at the first surface side of the insulating base material, the first surface including first and second regions, the plurality of metal pads being provided on the first region of the first surface, the first resin covering the plurality of metal pads and the second region of the first surface;
partially removing the first resin at the first surface side of insulating base material so that the plurality of metal pads are exposed and a portion of the first resin contacting the second region of the first surface remains;
mounting a semiconductor element on one of the metal pads;
bonding a conductive member on the semiconductor element and another one of the metal pads, the conductive member electrically connecting the semiconductor element and said another one of the metal pads; and
forming a second resin, the second resin contacting the first resin and sealing the semiconductor element and the conductive member at the first surface side of the insulating base material.

9. The method according to claim 8, wherein
the plurality of metal pads are exposed by cutting the first resin along a surface of the plurality of metal pads.

10. The method according to claim 9, wherein
the metal pads each are partially cut together with the first resin.

11. The method according to claim 10, wherein
the first resin and the plurality of metal pads are cut by a cutting blade moving along the first surface of the insulating base member, and
a spacing between the first surface of the insulating base material and the cutting blade is set to be less than a thickness of the plurality of metal pads in a direction perpendicular to the first surface.

12. The method according to claim 8, wherein
the first resin is partially removed by plasma etching of the first surface side of the insulating base material.

13. The method according to claim 12, wherein
the first resin is etched such that the portion of the first resin contacting the first surface of the insulating base material has a thickness in a first direction perpendicular to the first surface, the thickness of the portion of the first resin being less than a thickness in the first direction of the metal pads.

14. The method according to claim 8, wherein
metal layers are formed respectively on the plurality of metal pads by plating, and
the metal layers includes material different from material of the plurality of metal pads.
